(19) United States
(12) Patent Application Publication
(10) Pub. No.: US 2024/0420941 A1
(43) Pub. Date: Dec. 19, 2024

(54) TEMPERATURE CONTROL PLASMA SOURCE ANALYZER ARRANGEMENT AND TEMPERATURE-CONTROLLED GAS FLOW-PLASMA SOURCE ANALYSIS METHOD

(71) Applicant: GEOMAR Helmholtz Centre for Ocean Research Kiel, Kiel (DE)

(72) Inventor: Jan Fietzke, Rosenfeld (DE)

(21) Appl. No.: 18/744,388

(22) Filed: Jun. 14, 2024

(30) Foreign Application Priority Data
Jun. 16, 2023 (DE) 10 2023 115 854.6

(51) Int. Cl. H01J 49/04; H01J 49/00; H01J 49/10

(52) U.S. Cl. CPC H01J 49/049; H01J 49/0031; H01J 49/0486; H01J 49/105

(57) ABSTRACT

The invention relates to a temperature control plasma source analyzer arrangement (1) comprising a plasma source (3), at least one preheating device (2), preferably comprising a temperature control means (21) for heating and/or cooling at least one gas flow of the plasma source (3) relative to room temperature, of, and an analyzer (4); wherein the at least one gas flow comprises a sample gas flow (5) with a sample aerosol (15), the plasma source (3) is configured to ionize the sample aerosol (15) of the sample gas flow (5), and the analyzer (4) is configured to analyze the ionized sample aerosol (15); wherein the preheating device (2) is configured to increase temperature of the at least one gas flow; the preheating device (2) is located in front of the plasma source (3) so that the at least one gas flow reaches the plasma source (3) only after leaving the preheating device (2); the preheating device (2) is configured to controllably increase the temperature of the at least one gas flow; and the arrangement (1) is designed as a modular system, wherein the preheating device (2) is constructed as a separate module

The invention relates to a temperature control plasma source analyzer arrangement comprising a plasma source, at least one means of controlling temperature, e.g. preheating or cooling at least one gas flow of the plasma source, and an analyzer, wherein the at least one gas flow comprises a sample gas flow with a sample aerosol and the sample aerosol of the sample gas flow is ionized in the plasma source and analyzed in the analyzer.

The invention furthermore relates to a temperature-controlled gas flow-plasma source analysis method using a temperature control plasma source analyzer arrangement.

According to the invention, temperature-supported is to be understood as a regulated deviation from room temperature; i.e. a heating or cooling.

In the case of increasing the temperature in a defined region of a gas inflow compared to the ambient temperature, controlling temperature in the sense of the invention thereby refers to heating and in case of lowering the temperature in a defined region of a gas inflow thereby refers to cooling. There are exceptions thereto, for example a relative heating of a gas inflow can also occur in the cooling inflow, even while functionally cooling.

Various known analysis methods utilize a particle flow of electrically charged particles extracted from a particle source. For example, mass spectrometers with inductively coupled plasma (Inductively Coupled Plasma Mass Spectrometry, ICP-MS) are known in relation to performing trace analyses.

In ICP-MS, ionized argon is first induced by a high-frequency current and the sample is heated to 5000-10000° C. The atoms are thereby ionized and a plasma produced. The ions generated in the plasma are thereafter accelerated toward the analyzer of the mass spectrometer. Measuring instrumentation detect the individual elements and their isotopes there. ICP-MS can achieve detection limits in the range of ng/l or sub ng/l for most of the elements of the periodic table. Furthermore, the method is characterized by an extremely high linear range in the quantitative determination of up to more than nine orders of magnitude (g/l-pg/l).

In addition to quantitative analytical tasks, highly precise isotope analysis can also be carried out with the known ICP-MS. In the known device design, a sample gas flow, an auxiliary gas flow and a cooling gas flow are thereby provided at room temperature. The cooling gas flow prevents melting of the quartz tube in which the plasma is operated. The auxiliary gas flow supplies most of the plasma. The sample gas flow is supplied centrally and is the carrier for the sample material, thus the sample aerosol. When the sample gas flow is introduced into a plasma with the sample aerosol, it is gradually heated up intensely by the surrounding plasma. The sample gas flow thereby creates a cooler region in the core of the plasma, which only increases in temperature gradually over the distance from the sample injection to the point of extraction. The entrained sample aerosol is thereby gradually evaporated and ionized by the increasingly hotter sample gas flow. Once the sample material is evaporated from the primary aerosol (particles or droplets), it is subject to diffusion processes which convey the sample material to outer regions of the plasma. This material is lost with respect to extraction (sampling). Since diffusion is dependent on mass, diffusion losses are much higher for light ions than for heavy ions.

Alternatively, measuring instrumentation can detect the optical emission of characteristic radiation during the deexcitation of previously generated ions (energetically excited). This method (ICP-OES: inductively coupled plasma optical emission spectrometry) is also able to determine the chemical composition of the sample.

In principle, that as was previously described with respect to ICP sources applies in general to analytical plasmas. A plasma is produced and maintained, a sample is introduced and converted into ions, and measuring instrumentation process the ions.

The prior art shows inductively coupled plasma mass spectrometers (ICP-MS) as technical apparatus for a highly sensitive analysis method.

Printed publication DE10 2017 004 504 A1 shows a method and an apparatus for detecting electrically charged particles of a particle flow as well as a system for analyzing ionized components of an analyte, for example with an inductively coupled plasma mass spectrometer (ICP-MS).

Known from printed publication DE 10 2016 123 911 A1 is a heated transfer line which is suitable for connecting a gas chromatograph (GC) to a spectrometer. The transfer line has a heating arrangement which enables maintaining a uniform temperature profile, which improves the quality of the spectra. The transfer line further exhibits a low thermal mass and the heating can be regulated with the control unit of the GC.

In addition, printed publication U.S. Pat. No. 6,674,068 B1 discloses a time-of-flight (TOF) mass spectrometer and a method for TOF mass spectrometry analysis.

Printed publication US 2007 0 045 247 A1 shows an apparatus and a method for alignment of an inductively coupled plasma.

Furthermore, printed publication US 2015 0 235 827 A1 provides methods and systems for the automated tuning of multi-mode inductively coupled plasma mass spectrometers (ICP-MS). A “single click” optimization method is provided in certain embodiments for a multi-mode ICP-MS system which automates tuning of the system in one or more modes selected from the multiple modes, e.g. a vented cell mode, a reaction cell mode (e.g. dynamic reaction cell mode) and a collision cell mode (e.g. kinetic energy discrimination mode). Workflows and computational routines, including a dynamic range optimization technique, are presented which enable faster, more efficient, and more accurate tuning.

The prior art problems relate substantially to the mass-dependent ion losses (mass fractionation/mass bias/mass fractionation) that occur in analytical plasma sources, in particular in ICP-MS. These losses are predominantly attributed to the so-called “space charge effect” which is based on the repulsion of ions due to the Coulomb force that ions exert on each other after extraction from the plasma in the so-called interface to the mass spectrometer. The effect on the ions is dependent on mass (light ions are more vigorously repelled, or deviate farther from the central trajectory respectively, than heavy ions). However, it can be experimentally demonstrated that the space charge effect's contribution to mass fractionation in ICP-MS is overestimated. The vast majority of mass fractionation already takes place in the plasma. Once the sample enters the plasma with the sample gas flow, element-dependent and mass-dependent processes begin to have their effect. On the one hand, there is the element-dependent release of atoms from the sample aerosol. The gradual heating of the sample aerosol initially leads to a preferential release of the more thermally volatile components. In contrast, the releasing of components having high evaporation temperature (refractory) from the sample aerosol lags behind. In practice, this usually results in the sample aerosol still not being fully evaporated when the ions are extracted from the plasma. On the other hand, atoms/ions are subject to diffusion processes after having been released from the sample aerosol.

As a result, they gradually deviate from the original trajectory of the injected aerosol. This diffusion process is dependent on mass. Light atoms/ions are thereby lost faster and to a greater extent to regions of the plasma from which they are no longer accessible for extraction than heavy ones. Yet heavy atoms/ions are also subject to diffusion and lost for analysis through the described process. The heating rate and the residence time of the sample between injection into and extraction from the plasma are critical to optimizing release/ionization and diffusion processes. Long residence time/high heating improves the total ion yield from the sample aerosol (up to 100%) but loses most of the ions for extraction due to the described diffusion. Short residence times reduce the latter but come at the cost of the overall ion yield (mostly from incomplete sample vaporization).

One task is that of remedying the deficiencies existing in the prior art and achieving an overall improvement for existing devices.

In particular, compared to the prior art, a quantitatively and qualitatively better usability of the samples employed coupled with minimized diffusion losses is to be achieved.

Additionally, or alternatively, the analysis quality of existing systems shall be improved by integration or respectively adaptation of an apparatus to an existing device in a novel arrangement, in particular the ICP-MS. The goal is maximizing the amount of sample ions able to be extracted from the plasma.

Preferably, the novel arrangement should be of technically simple design, be able to be produced as a modular product and be flexibly usable as a module in existing systems in the novel arrangement.

Coupled with the task of increasing the amount of sample ions able to be extracted from the plasma, in particular the analytical detection sensitivity of the novel arrangement with implemented apparatus should be significantly higher compared to previous use without this apparatus.

Preferably, at the same time, the novel arrangement further is to solve the task of reducing and stabilizing the mass-dependent fractionation.

Furthermore, a method for using the arrangement with a device according to the prior art, in particular an ICP-MS or the like, should be provided.

One or more of these tasks are solved in particular with a temperature control plasma source analyzer arrangement comprising
a plasma source
at least one temperature control means, in particular a preheating device and/or cooling device, of at least one gas flow of the plasma source and
an analyzer;

wherein
the at least one gas flow comprises a sample gas flow with a sample aerosol and
the sample aerosol of the sample gas flow is ionized in the plasma source and analyzed in the analyzer;

wherein
the temperature of the at least one gas flow is increased in the preheating device or lowered in a cooling device, e.g. in the cooling gas feed;
the preheating/cooling device is designed to be spatially located in front of the plasma source so that the at least one gas flow only reaches the plasma source subsequent the preheating device;
the preheating device controllably increases the temperature of the at least one gas flow;
the cooling device controllably lowers the temperature of the at least one gas flow;
the arrangement is designed as a modular system, wherein the preheating/cooling device is constructed as a separate module.

In some embodiments, the preheating device is configured to preheat the sample gas flow of the plasma source such that the sample gas flow has, throughout an entire period of time between a start of an operation of the analyzer and a stop of the operation of the analyzer, a constant injection temperature T_{IN} at an injection site where the sample gas flow is introduced in the plasma source.

In some embodiments, the preheating device is configured to preheat the sample gas flow of the plasma source such that the sample gas flow has a constant injection temperature T_{IN} at the injection site which is higher than 200° C., in some embodiments higher than 400° C., in some embodiments higher than 900° C., and up to 1100° C.

In some embodiments, the preheating device is configured to preheat the sample gas flow of the plasma source such that the sample gas flow has, preferably throughout the entire period between the start of the operation of the analyzer and the stop of operation of the analyzer, a variable injection temperature at the injection site where the sample gas flow is introduced into the plasma source, wherein the variable injection temperature varies, in particular oscillates, more particular oscillates sinusoidally, around and/or about a predetermined constant temperature value, preferably with a deflection or amplitude whose value is less than 5%, in particular less than 2.5%, more preferably less than 1.25% of the predetermined constant temperature value.

Here, in case of an oscillation of the variable injection temperature, the cycle period of the oscillation may be in the range of 5 min to 15 min, preferably 10 min.

In some embodiments, the preheating device is configured to preheat the sample gas flow of the plasma source such that the sample gas flow has a variable injection temperature with a predetermined constant temperature value which is equal to or higher than 200° C., in some embodiments equal to or higher than 400° C., in some embodiments equal to or higher than 900° C., and up to 1100° C.

In some embodiments, the variation of the variable injection temperature may be achieved by supplying a varying power to the at least one preheating device, wherein the supplied varying power depends on and/or is proportional to the desired variable injection temperature.

In tests, in which the sample gas flow was preheated such that the sample gas flow had a constant injection temperature T_{IN} at the injection site of about 400° C. and a mass spectrometer was used as the analyzer, optimal performance of the arrangement according to the invention was achieved at 550 W plasma power (so-called rf power), i.e., at substantially lower plasma power than with a corresponding arrangement having no preheating device (“normal operation”), in which the optimal performance is achieved at a plasma power in the range of 1000 to 1400 W.

Additionally, all gas flows leading to the plasma source could be reduced when using the arrangement according to the invention by approx. ⅓ compared to the normal operation.

Despite the lower plasma power used, the oxide formation rate (ThO/Th), which is a common criterion for plasma tuning, could be kept below 0.5%.

In comparative measurements using laser ablation on a standard (NIST-SRM610) under identical laser settings, the following increase factors in signal strength (IY—ion yield) were achieved (preheated with preheating device vs. normal operation):

IY(400° C.)/IY(25° C.)
Na23 5.2+−0.3
Si28 5.0+−0.6
Rb85 4.1+−0.5
Sr88 3.6+−0.2
Y89 3.3+−0.4
In115 2.7+−0.3
Cs133 3.1+−0.1
Ba138 3.7+−0.3
Ce140 3.6+−0.3
Tb159 3.0+−0.2
Th232 2.9+−0.2
U238 3.0+−0.1

Accordingly, when using the arrangement according to invention, in some embodiments the sensitivity can be improved and a lower plasma power is required, as compared to the normal operation.

The preheating device can be designed as
externally heated metal capillaries or metal tubes and/or
internal heating elements and/or
heating coils and/or
heating filaments and/or
heating grids or heating braids and/or
external heating elements and/or
heating lines and/or
laser heating and/or
a pre-plasma and/or
electromagnetic radiation sources.

Additionally, a preheating device can comprise at least one control unit, at least one gas transfer line and at least one temperature control unit.

In particular, the controllable increase in temperature in the preheating device can be designed as
adjustable fixed control parameters and/or
adjustable control parameters with a temperature measuring element in a control loop.

In some embodiments, preheating the at least one gas flow reduces or allows for reducing a residence time of the sample gas flow with the sample aerosol in the plasma source, in some embodiments with respect to corresponding arrangements having no preheating device and being known from the prior art, preferably wherein a shortened residence time effects or allows for a reduction of diffuse losses of extractable ions and element fractionation.

The temperature-controlled gas flow-plasma source analysis method using a temperature control plasma source analyzer arrangement has the following steps:
setting control parameters in the preheating device;
feeding at least one gas flow into the preheating device at a start temperature T_{S}, wherein the at least one gas flow comprises a sample gas flow with a sample aerosol;
heating the at least one gas flow in the preheating device to an injection temperature T_{IN}, wherein T_{S}<T_{IN};
feeding the sample gas flow into the plasma source at injection temperature T_{IN};
heating the sample gas flow in the plasma source to extraction temperature T_{EX} with ionization of the sample aerosol of the sample gas flow, wherein T_{S}<T_{IN}<T_{EX};
extracting ionized sample aerosol at extraction temperature T_{EX} and feeding to the analyzer;
performing the analysis of the ionized sample gas flow in the analyzer.

In some embodiments, heating the at least one gas flow in the preheating device to the injection temperature T_{IN} comprises heating the sample gas flow in the preheating device to an injection temperature T_{IN} which is constant throughout an entire period of time between a start of an operation of the analyzer and a stop of the operation of the analyzer.

In some embodiments, the sample gas flow is heated in the preheating device to an injection temperature T_{IN} which is higher than 200° C., in some embodiments higher than 400° C., in some embodiments higher that 900° C., and up to 1100° C.

In some embodiments, heating the at least one gas flow in the preheating device to the injection temperature comprises heating the sample gas flow in the preheating device to a variable injection temperature, wherein the variable injection temperature varies, in particular oscillates, more particular oscillates sinusoidally, around and/or about a predetermined constant temperature value, preferably with a deflection or amplitude whose value is less than 5%, in particular less than 2.5%, and more preferably less than 1.25% of the predetermined constant temperature value.

In some embodiments, the sample gas flow is heated in the preheating device to a variable injection temperature with a predetermined constant temperature value which is equal to or higher than 200° C., in some embodiments equal to or higher than 400° C., in some embodiments equal to or higher that 900° C., and up to 1100° C.

Preferably, the start temperature T_{S} of the at least one gas flow is room temperature.

In particular, the at least one gas flow whose temperature is increased in the preheating device can be formed from
the sample gas flow or
the sample gas flow and the auxiliary gas flow or
the sample gas flow and the cooling gas flow or
the sample gas flow and the auxiliary gas flow and the cooling gas flow.

The sample aerosol in the sample gas flow can be partially pre-evaporated in the preheating device.

In some embodiments, heating the at least one gas flow in the preheating device to the injection temperature T_{IN} is carried out such that a share of energy to be applied in the plasma source for the evaporation and ionization of the sample aerosol in the sample gas flow is reduced, in some embodiments with respect to corresponding methods in which no preheating device is used and which are known from the prior art.

The setting of control parameters in the preheating device can also be realized via fixed control parameters and/or control parameters with a temperature measuring element in a control loop.

The temperature control plasma source analyzer arrangement can be used for controlling the temperature of at least one gas flow of a plasma source using the temperature-controlled gas flow-plasma source analysis method.

The analysis quality of a known plasma source is modified and thus improved by a respective adaptive module for temperature-supported, controllable gas feed in the region of the sample gas feed (also auxiliary gas feed and/or cooling gas feed where applicable) of the plasma source.

The subject matter of the invention is directed toward an arrangement with a method for the regulated temperature control/preheating of at least the sample gas flow prior to injection into the plasma source. The purpose of this regulated temperature control is to specifically influence the behavior of the sample material in the plasma environment. As has been the case up to now, the sample material is thereby primarily produced by a suitable apparatus and mixed with a sample gas flow. This admixing can ensue, for example, via sample atomizers for liquid samples (with or without aerosol drying) or laser ablation for solid samples. Instead of introducing the sample gas flow directly into the plasma source, it is thermally adapted in the inventive arrangement by the described method.

A plasma of a plasma medium, into which the sample gas flow is introduced as a carrier medium of the sample aerosol/analyte, is generated in the plasma source by applying a high-frequency alternating field. The components of the analyte, in particular individual atoms and/or their isotopes, can be ionized in the plasma and can be brought out of the plasma as an ion beam via pinhole apertures, the so-called sampler cone and skimmer cone, and thereafter analyzed in an analyzer, in particular a mass spectrometer. The results of such an in particular mass spectrometric analysis and/or the reliability of same thereby depend on the plasma conditions in the plasma source.

Intense heating of the sample gas flow with the sample aerosol prior to injection/feed into the plasma reduces the amount of energy required for the release and ionization and is able to combine high ion yields with low diffusion losses at shorter residence times.

The significant increase in injection temperature when the sample gas flow is brought into the plasma can lead, for example, to partial evaporation of the sample aerosol/sample material even prior to injection into the plasma. The further course of the process (conversion of the sample into ions) is also thermally supported and a more advantageous energy distribution for the processes results, which allows the required residence time of the sample in the plasma to be reduced. This reduction in residence time thus also allows an increased flow velocity or flow rate of the sample gas flow. The shortened residence time, or higher velocity of the pre-evaporated sample respectively, reduces the known sample losses through radial diffusion and a substantially higher proportion of ions remains in the axial region of the plasma and can then be extracted (“sampled”) with lower losses. Due to the strong mass dependency of diffusion, the gain in usable ions is particularly high for the light ions. Heavy ions also show a reduction in diffusive losses, albeit to a lesser relative extent than light ions.

The subject matter of the invention, thus the inventive arrangement and the method directed thereto, enables at least partially decoupling the processes taking place in the plasma. A quantitatively and qualitatively better usability of the sample employed is achieved and losses due to diffusion can be minimized.

The temperature control plasma source analyzer arrangement can be produced as a modular product. The preheating and/or cooling device can be easily integrated into known analyzers with plasma sources or adapted to such systems respectively.

The temperature control of a medium can thereby be individually regulated in analytical devices with plasma sources.

The preheating device is intended to be in particular integrated between the existing apparatus for generating samples (sample transported with sample gas) and an ICP plasma source. The preheating device is to thereby control the temperature of the sample gas flow transporting the sample/sample aerosol to a temperature specified by the user prior to it being fed into the ICP plasma source.

In describing the invention, reference will be made to the accompanying figures in the following description of the figures, wherein this serves in illustrating the invention and is not to be considered as limiting. Shown are:

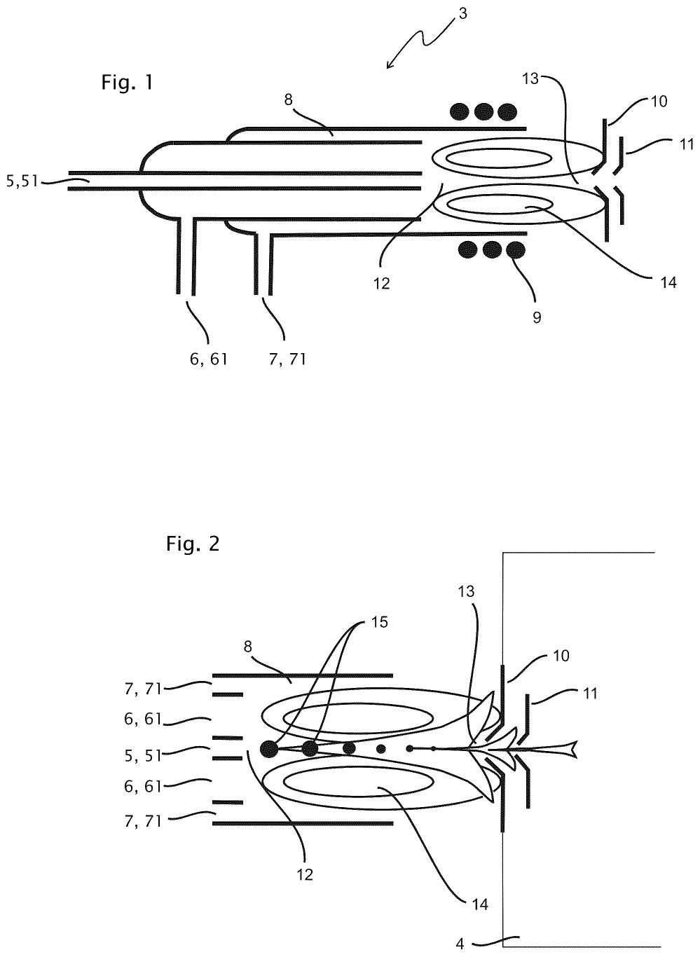

FIG. 1 an exemplary embodiment of a plasma source designed as an ICP plasma source according to the prior art;

FIG. 2 an exemplary schematic depiction of the processes in the plasma of a plasma source according to FIG. 1;

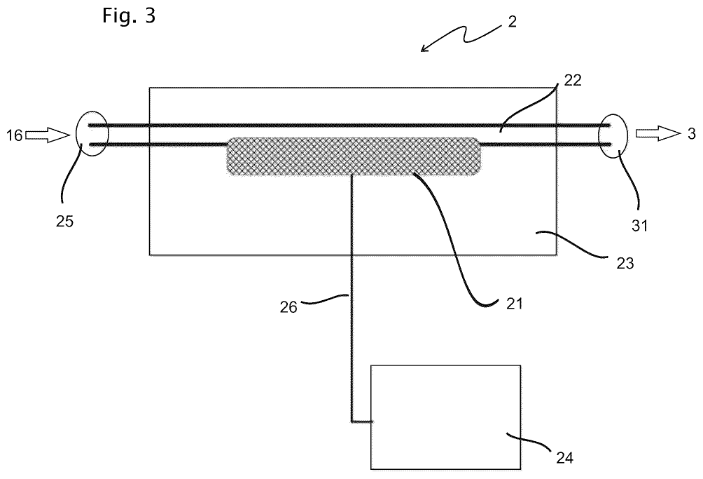

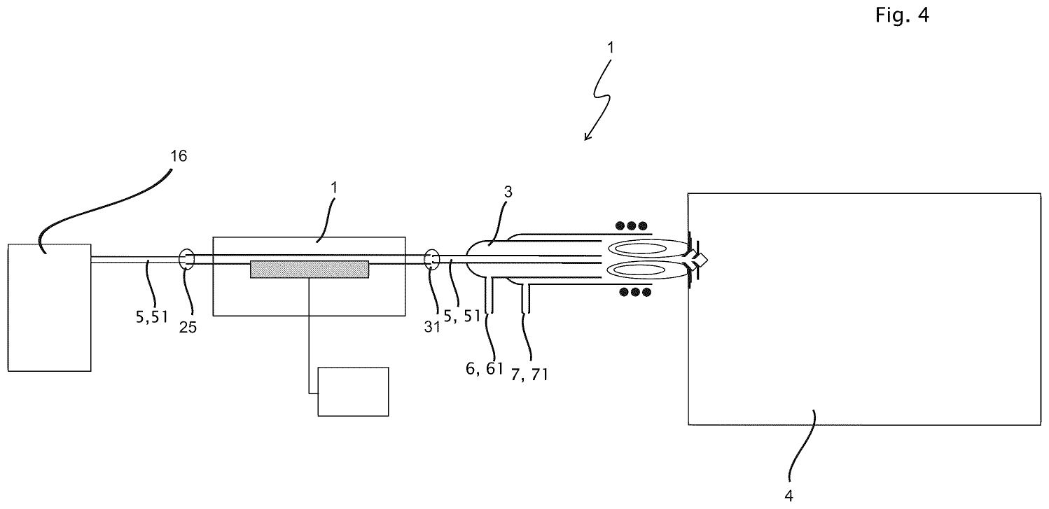

FIG. 3 an exemplary embodiment of the basic structure of a preheating device of a temperature control plasma source analyzer arrangement according to the invention;

FIG. 4 an exemplary first embodiment of a temperature control plasma source analyzer arrangement according to the invention;

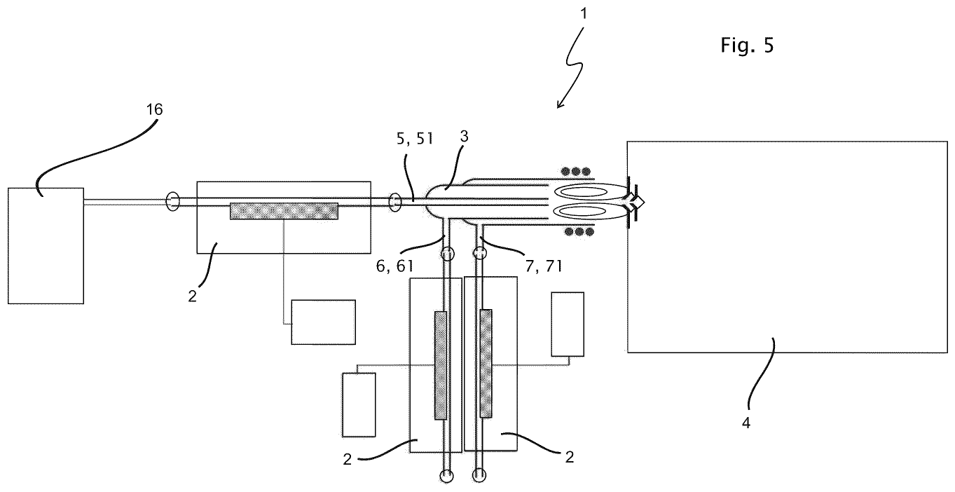

FIG. 5 an exemplary second embodiment of a temperature control plasma source analyzer arrangement according to the invention;

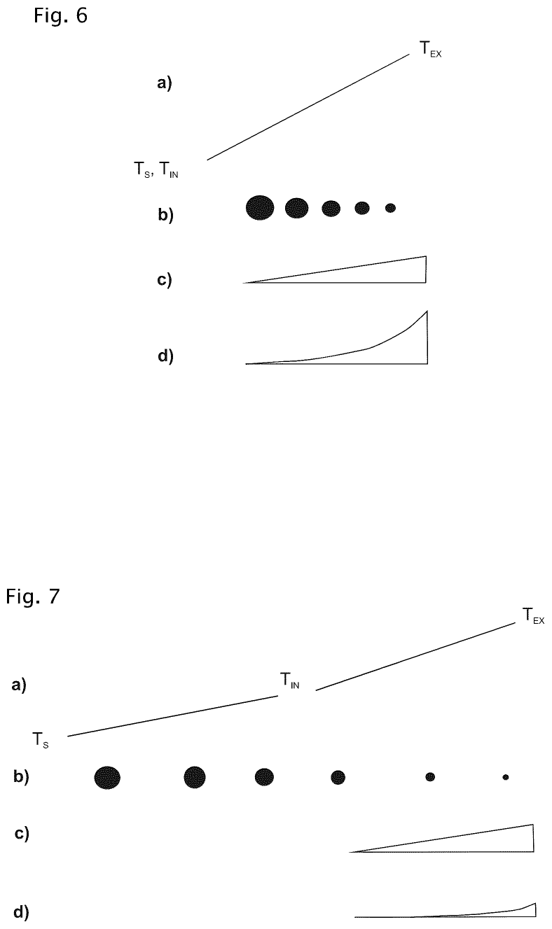

FIG. 6 an exemplary depiction of various states in the process flow of a prior art ICP-MS comprising a) temperature profile, b) sample aerosol evaporation, c) total ionization and d) diffusion loss;

FIG. 7 an exemplary depiction of various parameters in the process flow of the temperature-controlled gas flow-plasma source analysis method according to the invention comprising
a) temperature profile, b) sample aerosol evaporation, c) total ionization and d) diffusion loss and

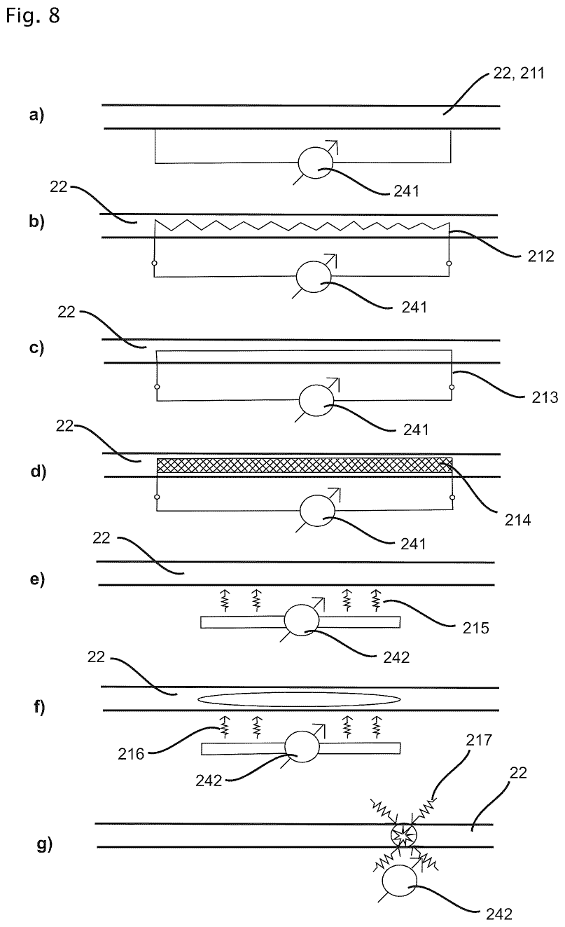

FIG. 8 an exemplary selection of design variants of the temperature control unit 21 of the preheating device 2 (FIG. 8a) to g)).

FIG. 1 shows the structure of a plasma source 3 designed as an ICP plasma source according to the prior art. A plasma 14 is inductively excited with radio waves inside a plasma torch 8 via an RF coil 9. The operationally required gases are supplied to the plasma torch 8 via the inlets for the sample gas feed 51, auxiliary gas feed 61 and cooling gas feed 71. The sample aerosol 15 is fed into the plasma 14 with the sample gas flow 5 at the injection site of the sample gas flow 12. After evaporation of the sample aerosol 15 and ionization, the ions are extracted from the plasma at the site of ion extraction 13. This is done via the sampler cone 10 and the skimmer cone 11.

FIG. 2 schematically depicts an example of the processes in the plasma 14 of a plasma source according to FIG. 1. The arrangement of the gas feeds 51, 61, 71 within the plasma torch 8 corresponds to FIG. 1. The sample aerosol 15 is introduced into the plasma 14 at the injection site of the sample gas flow 12. The sample aerosol 15 is progressively evaporated as it passes through the plasma 14 from the injection site 12 to the extraction site 13 (represented in the depiction by the decreasing size of the black circles representing the sample aerosol 15). Furthermore, the released atoms of the sample are gradually ionized by the energy of the surrounding plasma 14. Released atoms/ions are subject to diffusion and are lost from the central trajectory to outer regions of the plasma 14 (diffusion loss). Only the portion of ions that can be captured by the sampler cone 10 at the extraction site 13 is usable and is conveyed to the interface of the analyzer 4 preferentially designed as a mass spectrometer.

FIG. 3 shows an exemplary embodiment of the basic structure of a preheating device 2 of a temperature control plasma source analyzer arrangement 1 according to the invention. Same comprises a temperature control unit 21, a gas transfer line 22, a housing insulation 23 and a control unit 24. The sample gas flow 5 with the sample aerosol 15 is directed through the preheating device 2 for the purpose of temperature control. The temperature control unit 21 is in contact with the gas transfer line 22 for the purpose of temperature control of the sample aerosol 15. The temperature control unit 21 is connected to the control unit 24 via a connecting cable 26. The control unit 24 regulates the temperature controlling operation of the temperature control unit 21 for the purpose of controlling the temperature of the sample aerosol 15. In this context, temperature control means the regulated temperature change of the sample aerosol 15 in the sample gas flow 5 from the start temperature T_{S} to the injection temperature T_{IN}, wherein T_{S}<T_{IN}, so that the share of energy to be applied in the plasma source 3 for the evaporation and ionization of the sample aerosol 15 in the sample gas flow 1 is reduced.

To shield against the environment (thermal, electrical, etc.) as well as to protect the user and the existing measuring equipment, the cited components are typically located in an insulating housing 23. In order to easily integrate the preheating device 2 into existing measuring apparatus as a module, it is typically equipped with two adapters 25, 31 which enable connection to both the existing primary sample apparatus 16 as well as to the plasma source 3.

FIG. 4 shows an exemplary first embodiment of a temperature control plasma source analyzer arrangement 1 according to the invention. A preheating device 2 is installed here upstream of a plasma source 3 with a downstream analyzer 4, following the primary sample apparatus 16. The preheating device 2 thus serves in this embodiment in heating the sample gas flow 5 with the sample aerosol 15.

It is possible to integrate the preheating device 2 as an independent module in a system according to the state of the art.

FIG. 5 depicts an exemplary second embodiment of a temperature control plasma source analyzer arrangement 1 according to the invention. In this embodiment, all three gas flows, thus sample gas flow 5, auxiliary gas flow 6 and cooler gas flow 7, are each equipped with a preheating device 2 prior to entering the plasma source 3.

Moreover, an exemplary depiction of various states over the process flow of an ICP-MS according to the prior art, thus without preheating device 2, is shown in FIG. 6, comprising a) temperature profile, b) sample aerosol evaporation, c) total ionization and d) diffusion loss.

FIG. 6a depicts the temperature profile between injection site 12 and extraction site 13 during the passage of the sample aerosol 15 through the plasma 14. According to the prior art, the injection temperature T_{IN} corresponds to the start temperature T_{S}. The start temperature T_{S} is preferentially room temperature. The temperature reaches the extraction temperature T_{EX} at the site of ion extraction 13.

FIG. 6b) shows a symbolic representation of the evaporation of the sample aerosol 15, depicted by the decreasing size of black circles representing the sample aerosol 15.

Looking at FIG. 6a) and FIG. 6b) simultaneously makes clear that the sample aerosol 15 continuously evaporates further as the temperature increases over the course of the process.

FIG. 6c) depicts the gradual increase of the ions generated from the sample aerosol 15 (total ionization) over the course of the process. Ionization is almost linear over the entire process of increasing the temperature in the plasma source 3.

In addition, FIG. 6d) depicts the gradual increase of ions lost by diffusion to outer plasma regions, which cannot be used for extraction (diffusion loss), over the course of the process.

A diffusion loss occurs throughout the entire process of increasing the temperature in the plasma source 3. As the process progresses, however, the diffusion loss no longer increases linearly but rather exponentially. Light ions are far more affected by radial diffusion into the surrounding plasma 14 than heavy ions.

The various states 6a) to 6d) over the course of the process are all related to one another.

FIG. 7 shows an exemplary depiction of various parameters over the course of the temperature-controlled gas flow-plasma source analysis method process according to the invention using a temperature control plasma source analyzer arrangement 1 for an aerosol heating application, comprising a) temperature profile, b) sample aerosol evaporation, c) total ionization and d) diffusion loss.

FIG. 7a depicts the temperature profile between start temperature T_{S} and extraction temperature T_{EX}. The preheating device 2 initially increases the start temperature T_{S} to the injection temperature. T_{IN}. T_{S}<T_{IN} applies. Thus, the sample aerosol 15 is introduced into the plasma 14 at the injection site 12 at the significantly higher temperature T_{IN} instead of start temperature T_{S}. There is a further increase in temperature in the plasma 14 to extraction temperature T_{EX}. T_{S}<T_{IN}<T_{EX} applies.

FIG. 7b) shows a symbolic representation of the evaporation of the sample aerosol 15, depicted by the decreasing size of black circles representing the sample aerosol 15.

Looking at FIG. 7a) and FIG. 7b) simultaneously makes clear that the sample aerosol 15 continuously evaporates as the temperature increases over the course of the process. The evaporation has already started in the preheating device 2 and steadily continues in the plasma source 3. As depicted here, given a sufficiently high enough T_{IN}, initial aerosol evaporation can already occur within preheating device 2 due to the preheating effect.

In some embodiments, the preheating device 2 is configured to preheat the sample gas flow 5 of the plasma source 3 such that the sample gas flow 5 has, throughout an entire period of time between a start of an operation of the analyzer 4 and a stop of the operation of the analyzer 4, a constant injection temperature T_{IN} at the injection site 12 where the sample gas flow 5 is introduced in the plasma source 3.

In this case, the preheating device 2 can be configured to preheat the sample gas flow 5 of the plasma source 3 such that the sample gas flow 5 has a constant injection temperature T_{IN} at the injection site 12 which is higher than 200° C., in particular higher than 400° C., in some embodiments higher than 900° C., and up to 1100° C.

In some embodiments, the preheating device 2 is configured to preheat the sample gas flow 5 of the plasma source 3 such that the sample gas flow 5 has, preferably throughout the entire period between the start of the operation of the analyzer and the stop of operation of the analyzer 4, a variable injection temperature at the injection site 12 where the sample gas flow 5 is introduced into the plasma source 3, wherein the variable injection temperature varies, in particular oscillates, more particular oscillates sinusoidally, around and/or about a predetermined constant temperature value, preferably with a deflection or amplitude whose value is less than 5%, in particular less than 2.5%, more preferably less than 1.25% of the predetermined constant temperature value.

In this case, the preheating device 2 can be configured to preheat the sample gas flow 5 of the plasma source 3 such that the sample gas flow 5 has a variable injection temperature with a predetermined constant temperature value which is equal to or higher than 200° C., in some embodiments equal to or higher than 400° C., in some embodiments equal to or higher than 900° C., and up to 1100° C.

FIG. 7c) depicts the gradual increase of the ions generated from the sample aerosol 15 (total ionization) over the course of the process. Ionization is almost linear over the process of increasing the temperature in the plasma source 3. No ionization takes place in the preheating device 2.

Furthermore, FIG. 7d) depicts the gradual increase of ions lost by diffusion to outer plasma regions, which cannot be used for extraction (diffusion loss), over the course of the process. Light ions are much more strongly affected by radial diffusion into the surrounding plasma 14 than heavy ions.

A diffusion loss occurs as a result of the process of increasing the temperature in the plasma source 3. As the process progresses, however, the diffusion loss no longer increases linearly but exponentially. The preheating device 2 enables realizing a faster transfer of the sample aerosol 15, for example by means of a higher flow rate of the sample gas flow 5, which leads to a decrease in diffusion loss. No diffusion loss takes place in the preheating device 2.

The various states 7a) to 7d) over the course of the process are all related to one another.

The sample gas flow 5 is strongly preheated in the preheating device 2 prior to injection, which leads to a significant increase in the injection temperature T_{IN}. Ideally, such a temperature is reached that part of the evaporation of the sample aerosol 15 has already taken place at the injection site 12. This thus thermally supports the further course of the process; only just a small difference between the injection temperature T_{IN} and the extraction temperature T_{EX} is required. The energy for the processes is now divided up, part of it already being supplied prior to injection into the plasma 14 and thus reducing the remaining amount of energy to be applied in the plasma. Lowering the amount of energy allows a reduction of the required residence time of the sample aerosol 15 in the plasma 14 (less energy needs to be transmitted at essentially the same power). This reduction in residence time thus allows an increased flow velocity/flow rate of the sample gas flow 5. The shortened residence time, or higher velocity of the pre-evaporated sample aerosol 15 respectively, reduces sample losses due to radial diffusion. A higher proportion of ions remains in the axial region of the plasma 14 and can be extracted (“sampled”). Due to the strong mass dependency of diffusion, the gain in usable ions is particularly high for the light ions. Yet heavy ions also show a reduction in diffusive losses, albeit to a lesser extent.

FIG. 8 shows a selection of possible variants of the design of the temperature control unit 21 able to be used in the preheating device 2, each in this example with regulation of the heating voltage 241 or respectively energy 242.

FIG. 8a) shows the direct heating of the gas transfer line 22 or a part thereof as heating line 211.

In FIG. 8b) a heating coil 212 located within the gas transfer line 22 is used.

It is also possible to use a heating filament 213 located within the gas transfer line 22 as shown in FIG. 8c).

FIG. 8d) shows a heating grid/heating braid 214 located within the gas transfer line 22.

In FIG. 8e), the heating of the gas transfer line 22 is realized by an external heating element 215.

The external excitation of a pre-plasma 216 as shown in FIG. 8f) constitutes a further possibility for heating the sample gas flow 5 within the gas transfer line 22.

A focused excitation of the sample gas flow 5 in the gas transfer line 22 by laser 217 as shown in FIG. 8g) is also possible.

The higher the achievable temperature during preheating of the sample gas flow 5, the shorter the achievable residence time of the sample aerosol 15 in the plasma 14. The shorter the residence time, the lower the diffuse losses of extractable ions and the element fractionation.

The overall yield of measurable ions is thus increased, wherein the light ions, which are otherwise most affected by loss, benefit disproportionately.

The stated control parameters in FIG. 8 are only intended for informational purposes. Controllable heating voltage can be equally replaced by a controllable heating current flow. Controllable heating energy can be equally replaced by a heating power, heating voltage or a heating current flow.

In the simplest case, an operator would set a fixed control parameter and feed the sample gas flow 5 into the plasma source 3 at the temperature resulting after thermal stabilization. The temperature reached by the sample gas flow 5 is not measured/controlled.

Additionally, measuring the temperature reached by the sample gas flow 5 may be desirable. To that end, the respective arrangement can be expanded by way of suitable temperature measuring elements. The temperature data thereby obtained can then be used to automatically regulate the heating parameter. In this regulated case, an operator can specify a target temperature and the preheating device 2 independently regulates the heating power by measuring the temperature and adjusting the control parameter in order to ensure a stable and defined heating process.

Inventive in the sense of this application is the use of sample gas flow/aerosol preheating in order to partially decouple the processes taking place in the plasma. This thereby achieves better and more complete usability of the sample aerosol employed and minimizes losses (through diffusion).

A further advantage of the arrangement and method according to the invention can be described. When the sample aerosol has already been for the most part pre-evaporated, or complete evaporation is at least supported later in the plasma, unevaporated sample residues will survive the transfer through the plasma to a significantly lesser extent. Since these would otherwise lead to deposits/encrustations on the sampler cone and skimmer cone, reducing/preventing unevaporated residues after plasma transfer is desirable. These encrustations would otherwise lead to a reduction in the aperture cross section, the material transfer would be reduced, and the number of usable ions would be reduced. The device must be switched off in this case and the apertures cleaned. The proposed method should thus also reduce the need for such service work.

The advantages that can be achieved with the inventive arrangement using the inventive method are thus summarized:
lower element fractionation (increased matrix tolerance),
lower mass fractionation (more stable measurement conditions, fewer data corrections),
significantly increased ion yield (disproportionately for light ions) and
reduced depositing of incompletely evaporated sample in the extraction unit (reduced amount of maintenance).

### LIST OF REFERENCE NUMERALS

1 temperature control plasma source analyzer arrangement
2 preheating
21 temperature control unit
211 heating line
212 heating coil
213 heating filament
214 heating grid/braid
215 external heating element
216 pre-plasma with external excitation
217 focused laser excitation
22 gas transfer line
23 insulating housing
24 control unit
241 heating voltage regulation
242 energy regulation
25 adapter for preheating sample gas flow feed
26 temperature control unit/control unit connecting cable
3 plasma source
31 adapter for plasma source sample gas flow feed
4 analyzer
5 sample gas flow
51 sample gas flow feed
6 auxiliary gas flow
61 auxiliary gas flow feed
7 cooling gas flow
71 cooling gas flow feed
8 plasma torch (quartz glass torch)
9 RF coil
10 sampler cone
11 skimmer cone
12 injection site of sample gas into plasma
13 ion extraction site from plasma
14 plasma
15 sample aerosol
16 primary sample apparatus

1. A temperature control plasma source analyzer arrangement comprising
a plasma source;
at least one preheating device, preferably comprising a temperature control means for heating, in particular preheating, and/or cooling at least one gas flow of the plasma source relative to room temperature; and
an analyzer;
wherein
the at least one gas flow comprises a sample gas flow with a sample aerosol;
the plasma source is configured to ionize the sample aerosol of the sample gas flow; and
the analyzer is configured to analyze the ionized sample aerosol; wherein
the preheating device is configured to increase the temperature of the at least one gas flow;
the preheating device is located in front of the plasma source so that the at least one gas flow reaches the plasma source only after leaving the preheating device;
the preheating device is configured to controllably increase the temperature of the at least one gas flow; and
the arrangement is designed as a modular system, wherein the preheating device is constructed as a separate module.

2. The temperature control plasma source analyzer arrangement according to claim 1, wherein the preheating device is configured to preheat the sample gas flow of the plasma source such that the sample gas flow has, throughout an entire period of time between a start of an operation of the analyzer and a stop of the operation of the analyzer, a constant injection temperature T_{IN} at an injection site where the sample gas flow is introduced in the plasma source; or
wherein the preheating device is configured to preheat the sample gas flow of the plasma source such that the sample gas flow has, preferably throughout the entire period between the start of the operation of the analyzer and the stop of operation of the analyzer, a variable injection temperature at the injection site where the sample gas flow is introduced into the plasma source, wherein the variable injection temperature varies, in particular oscillates, more particular oscillates sinusoidally, around and/or about a predetermined constant temperature value, preferably with a deflection whose value is less than 5%, in particular less than 2.5%, and more preferably less than 1.25% of the predetermined constant temperature value.

3. The temperature control plasma source analyzer arrangement according to claim 2, wherein the preheating device is configured to preheat the sample gas flow of the plasma source such that the sample gas flow has a constant injection temperature T_{IN} at the injection site which is higher than 200° C., in particular higher than 400° C., or
wherein the preheating device is configured to preheat the sample gas flow of the plasma source such that the sample gas flow has a variable injection temperature with a predetermined constant temperature value which is higher than 200° C., in particular higher than 400° C.

4. The temperature control plasma source analyzer arrangement according t claim 1, wherein the preheating device is designed as
externally heated metal capillaries or metal tubes and/or
internal heating elements and/or
heating coils and/or
heating filaments and/or
heating grids or heating braids and/or
external heating elements and/or
heating lines and/or
laser heating and/or
a pre-plasma and/or
electromagnetic radiation sources.

5. The temperature control plasma source analyzer arrangement according to claim 1,
wherein
the preheating device comprises at least one control unit, at least one gas transfer line and at least one temperature control unit.

6. The temperature control plasma source analyzer arrangement according to claim 1,
wherein
the preheating device is designed to controllably increase the temperature on the basis of
adjustable fixed control parameters and/or
adjustable control parameters with a temperature measuring element in a control loop.

7. The temperature control plasma source analyzer arrangement according to claim 1,
wherein
the preheating device is designed to control a temperature in a cooling gas flow and/or an auxiliary gas flow on the basis of
adjustable fixed control parameters and/or
adjustable control parameters with a temperature measuring element in a control loop.

8. The temperature control plasma source analyzer arrangement according to claim 1, wherein
preheating the at least one gas flow reduces or allows for reducing a residence time of the sample gas flow with the sample aerosol in the plasma source, preferably wherein a shortened residence time effects or allows for a reduction of diffuse losses of extractable ions and element fractionation.

9. A temperature-controlled gas flow-plasma source analysis method using a temperature control plasma source analyzer arrangement according to claim 1 comprising the following steps:
setting control parameters in the preheating device;
feeding at least one gas flow into the preheating at a start temperature T_{S}, wherein the at least one gas flow comprises a sample gas flow with a sample aerosol;
heating the at least one gas flow in the preheating device to an injection temperature T_{IN}, wherein T_{S}<T_{IN};
feeding the sample gas flow into the plasma source at injection temperature T_{IN};
heating the sample gas flow in the plasma source to extraction temperature T_{EX} with ionization of the sample aerosol of the sample gas flow, wherein T_{S}<T_{IN}<T_{EX};
extracting ionized sample aerosol at extraction temperature T_{EX} and feeding to the analyzer;
performing the analysis of the ionized sample gas flow in the analyzer.

10. The temperature-controlled gas flow-plasma source analysis method according to claim 1,
wherein heating the at least one gas flow in the preheating device to the injection temperature T_{IN} comprises heating the sample gas flow in the preheating device to an injection temperature T_{IN} which is constant throughout an entire period of time between a start of an operation of the analyzer and a stop of the operation of the analyzer; or wherein heating the at least one gas flow in the preheating device to the injection temperature T_{IN} comprises heating the sample gas flow in the preheating device to a variable injection temperature, wherein the variable injection temperature varies, in particular oscillates, more particular oscillates sinusoidally, around and/or about a predetermined constant temperature value, preferably with a deflection whose value is less than 5%, in particular less than 2.5%, and more preferably less than 1.25% of the predetermined constant temperature value.

11. The temperature-controlled gas flow-plasma source analysis method according to claim 10,
wherein the sample gas flow is heated in the preheating device to an injection temperature T_{IN} which is higher than 200° C., in particular higher than 400° C.; or
wherein the sample gas flow is heated in the preheating device to a variable injection temperature with a predetermined constant temperature value which is higher than 200° C., in particular higher than 400° C.

12. The temperature-controlled gas flow-plasma source analysis method according to claim 9,
wherein
the start temperature T_{S} is room temperature.

13. The temperature-controlled gas flow-plasma source analysis method according to claim 9,
wherein
the at least one gas flow with its temperature increased in the preheating device is formed from
the sample gas flow or
the sample gas flow and the auxiliary gas flow or
the sample gas flow and the cooling gas flow or
the sample gas flow and the auxiliary gas flow and the cooling gas flow.

14. The temperature-controlled gas flow-plasma source analysis method according to claim 9,
wherein
the sample aerosol in the sample gas flow is partially pre-evaporated in the preheating device.

15. The temperature-controlled gas flow-plasma source analysis method to claim 9,
wherein
the setting of control parameters in the preheating device is realized via
fixed control parameters and/or
control parameters with a temperature measuring element in a control loop.

16. The temperature-controlled gas flow-plasma source analysis method to claim 9, wherein
heating the at least one gas flow in the preheating device to the injection temperature T_{IN} is carried out such that a share of energy to be applied in the plasma source for the evaporation and ionization of the sample aerosol in the sample gas flow is reduced.

17. Use of the temperature control plasma source analyzer arrangement according to claim 1 utilizing the temperature-controlled gas flow-plasma source analysis method for controlling the temperature of at least one gas flow of a plasma source.
